(19) United States
(12) Patent Application Publication
(10) Pub. No.: US 2003/0073304 A1
(43) Pub. Date: Apr. 17, 2003

(54) Selective tungsten stud as copper diffusion barrier to silicon contact

(75) Inventors: Alfred Mak, Union City, CA (US); Jeong Soo Byun, Cupertino, CA (US); Moris Kori, Palo Alto, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/981,593

(22) Filed: Oct. 16, 2001

(51) Int. Cl. H01L 21/4763

(52) U.S. Cl. 438/643

(57) ABSTRACT

A method and apparatus for forming a metal interconnect is provided. A tungsten plug is first deposited by selective WCVD within a feature having an aspect ratio of 3:1 or greater to at least partially fill the feature. An IMP barrier layer is next deposited over the tungsten plug. A PVD copper seed layer followed by an ECP copper layer is then deposited over the barrier layer to fill the feature. The tungsten plug has a thickness of about 1,000 to about 5,000 angstroms and fills less than about 50% of the volume of the feature.

### BACKGROUND OF THE INVENTION

1. Field of the Invention

Embodiments of the present invention relate to a method and apparatus for manufacturing integrated circuit devices. More particularly, embodiments of the present invention relate to a method and apparatus for forming vias at the substrate contact level to form metal interconnects.

2. Background of the Related Art

Sub-quarter micron multilevel metallization is one of the key technologies for the next generation of very large scale integration (VLSI). The multilevel interconnects that lie at the heart of this technology possess high aspect ratio features, including contacts, vias, lines, or other apertures. Reliable formation of these features is very important to the success of VLSI and to the continued effort to increase quality and circuit density on individual substrates. Therefore, there is a great amount of ongoing effort being directed to the formation of void-free features having high aspect ratios (height:width) of 4:1 or greater.

Elemental aluminum (Al) and aluminum alloys are the most commonly used conductive materials to form lines and plugs in semiconductor processing because of aluminum's low resistivity, superior adhesion to silicon dioxide (SiO₂), ease of patterning, and high purity. Aluminum, however, has a relatively high resistivity and problems with electromigration, and as the width of electrical interconnections becomes narrower, the resistance of aluminum contributes significantly to the resistance-capacitance (RC) time delay of the circuit.

As a result, copper has recently become a choice metal for filling sub-micron high aspect ratio, interconnect features because copper and its alloys have lower resistivity than aluminum. However, copper and its alloys suffer from a greater propensity to electromigrate compared to aluminum due to the smaller size of the copper atom. Consequently, copper and its alloys tend to diffuse into silicon dioxide, silicon, and other dielectric materials, causing an increase in the contact resistance of the circuit.

Barrier layers have, therefore, become increasingly important to prevent copper from diffusing into the dielectric material or silicon substrate and compromising the integrity of the devices. Barrier layers typically consist of a refractory metal such as tungsten, titanium, tantalum, and nitrides thereof, and are deposited on the substrate prior to copper metallization. Barrier layers may be conventionally deposited using well known deposition techniques such as physical vapor deposition and chemical vapor deposition. However, conformal barrier layers are difficult to deposit in features having aspect ratios greater than about 3:1 using these conventional deposition techniques. Typically, the metal bridges the opening to the narrow features resulting in the formation of one or more voids or discontinuities within the feature. Since voids increase the resistance and reduce the electromigration resistance of the feature, features having voids make poor and unreliable electrical contacts.

A process known as selective CVD, has shown great promise for depositing a conformal metal layer, including a barrier layer, in high aspect ratio features. The selective CVD process involves the deposition of a metal film by contacting a reactive gas with a conductive surface on the substrate. The metal is less likely to grow on dielectric surfaces such as the field and aperture walls during normal processing conditions because dielectric surfaces have little to no conductive properties. For example, a metal may grow on the bottom of an aperture where a metal film, doped silicon, or metal silicide from the underlying conductive layer has been exposed. This is because the underlying metal films or doped silicon are electrically conductive, unlike the dielectric field and aperture walls, supplying the electrons needed for decomposition of the metal precursor gas and the resulting deposition of the metal. The result obtained through selective deposition is an epitaxial “bottom-up” growth of CVD metal in the apertures capable of filling very small dimension (<0.25 μm), high aspect ratio (>4:1) vias or contact openings.

Tungsten (W) has become a popular choice for barrier metal deposition using a selective CVD process. Precursor gases for selective tungsten deposition are commercially available and relatively inexpensive. In addition, tungsten has good thermal characteristics, relatively low resistivity, good opposition to electro-migration, and good step coverage. More importantly, tungsten does not form alloys with copper. Tungsten, however, is not a preferred conductive material because the resistivity of tungsten is about five times greater than that of copper and about three times greater than that of aluminum.

There is a need, therefore, for filling high aspect ratio features with conductive metals having higher electrical conductivity and improved electromigration resistance. There is also a need for a void-free fill of a high aspect ratio feature using conventional CVD and PVD processes.

### SUMMARY OF THE INVENTION

A method for forming a metal interconnect is provided. In one aspect, the method comprises depositing a metal plug to at least partially fill a feature having a width less than about 0.18 microns and an aspect ratio greater than about 3:1, depositing a barrier layer over the metal plug, and depositing a metal layer over the barrier layer. In another aspect, the method comprises depositing a tungsten plug having a thickness less than about 5,000 angstroms within a feature to reduce an aspect ratio thereof to less than about 3:1, depositing a barrier layer over the metal plug, and then depositing a metal layer over the barrier layer. In yet another aspect, the method comprises depositing a tungsten plug within a feature having a width less than about 0.18 microns to reduce an aspect ratio of the feature to less than about 3:1, wherein the tungsten plug is deposited by selective chemical vapor deposition, depositing a barrier layer over the metal plug, and then depositing a metal layer over the barrier layer.

### BRIEF DESCRIPTION OF THE DRAWINGS

So that the manner in which the above recited features, advantages and objects of the present invention are attained can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A-1E illustrate the steps for forming a metal interconnect in accordance with the method described below.

### DETAILED DESCRIPTION OF A PREFERRED EMBODIMENT

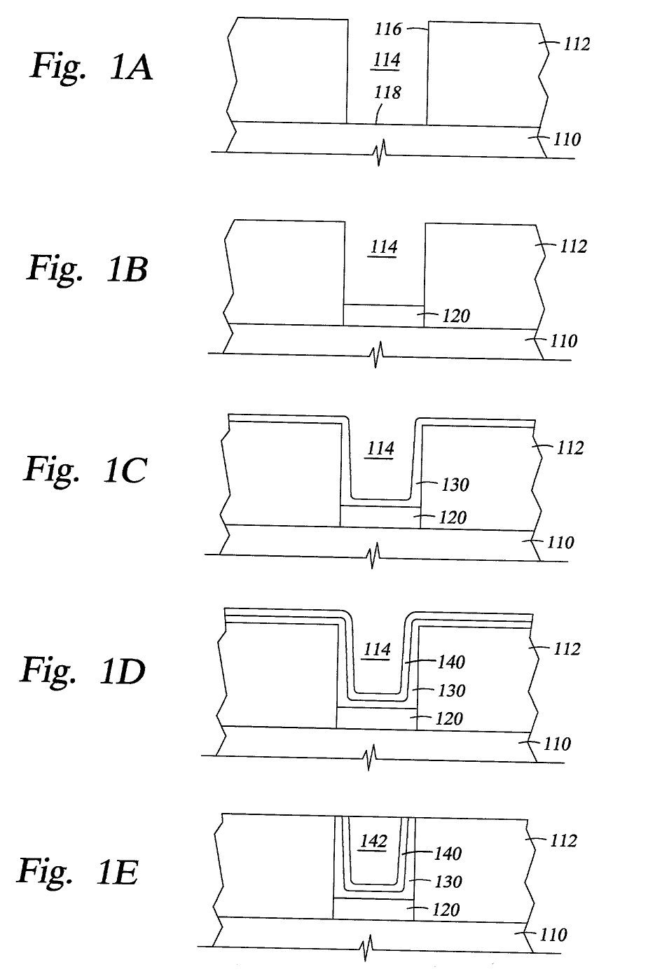

As illustrated in FIG. 1A, an integrated structure 100 is formed by depositing a dielectric layer 112 using conventional deposition techniques on a substrate 110 such as a silicon, doped silicon, germanium, gallium arsenide, glass, and sapphire for example. The dielectric layer 112 may be any dielectric material, whether presently known or yet to be discovered. For example, the dielectric layer 112 may be silicon dioxide, silicon carbide, or siloxy carbide, for example.

Once deposited, the dielectric layer 112 is etched to form a feature 114 therein using conventional and well-known techniques. The feature may be a via (as shown), contact, line, or any other interconnect feature. For simplicity and ease of description, however, the feature 114 will be further described with reference to a via 114.

The via 114 formed within the dielectric layer 114 provides steep sidewalls 116 and a floor 118, typically having an aspect ratio of 4:1 or greater. The floor 118 exposes at least a portion of the underlying substrate 110 that provides the electron donating surface for a subsequent selective chemical vapor deposition (CVD) metal process described below. Although not shown, a wire definition may be etched with the via 114 as is commonly known to form a dual damascene structure.

Referring to FIG. 1B, a metal plug 120 is at least partially formed within the via 114. In one aspect, the metal plug 120 fills less than about 50% of the volume of the via 114. Preferably, the metal plug 120 fills between about 10% and about 30% of the volume of via 114. Accordingly, the metal plug 120 may have a thickness between about 500 Å and about 5,000 Å depending on the dimensions of the via 114. For example, in a feature having a width of about 0.25 microns and a depth of about 1 micron (an aspect ratio of 4:1), a metal plug having a thickness of about 2,500 Å will reduce the aspect ratio to 3:1. Accordingly, by first depositing the metal plug, the aspect ratio of the feature is significantly reduced, thereby facilitating the deposition of a subsequent conformal barrier and metal layer. As stated above, conformal metal layers deposited using conventional deposition techniques are easily obtainable within features having aspect ratios of 3:1 or less.

Still referring to FIG. 1B, the metal plug 120 preferably includes tungsten (W) and is deposited within the via 114 using a selective CVD process although any metal or combinations of metals may be used, such as aluminum, tungsten, copper, tantalum, titanium, for example. A selective CVD process is the preferred deposition method, but any metal deposition process may be used such as physical vapor deposition (PVD).

Any chamber or integrated processing platform for practicing selective tungsten CVD may be used. For example, one CVD chamber which can be used is a WxZ® chamber available from Applied Materials, Inc. located in Santa Clara, Calif. The selective tungsten chemical vapor deposition (selective WCVD) process may be performed at chamber pressures of between about 1 torr and about 140 torr. In particular, the preferred chamber pressure is about 25 torr. The selective WCVD process provides deposition rates between about 300 Å/sec. and about 1000 Å/sec. at substrate temperatures of about 120° C. to about 240° C.

The selective WCVD process typically includes mixing and flowing a tungsten-containing gas such as WF₆, for example, and a reducing gas such as H₂ or SiH₄, at a rate of about 20 to about 200 standard cubic centimeters (sccm). A pressure of about 1 milliTorr to about 760 Torr, preferably from about 1 milliTorr up to about 200 milliTorr, is maintained during the deposition. The deposition temperature is between about 350° C. to about 500° C. when using H₂ as the reducing gas. The temperature is between about 200° C. to about 400° C. when using SiH₄ as the reducing gas. When the reducing gas is hydrogen, the WF₆ to H₂ ratio is about 1:50 to about 1:1000 in parts by volume. When the reducing gas is SiH₄, the ratio of WF₆ to SiH₄ is about 10:1 to about 1:1.5 in parts by volume.

The mixture of tungsten-containing gas and reducing gas may be accompanied by nitrogen and a carrier gas, such as helium or argon, flowing at a rate within a range of from about 10 to about 1000 sccm. The gases react and deposit a tungsten plug on the substrate 110 within the via 114. Finally, the chamber is purged by increasing the argon, nitrogen, and hydrogen flow rates to about 100 sccm.

The tungsten plug 120 is deposited from the floor 118 upward to partially fill the via 114 without any substantial tungsten deposition on the side walls 116. The deposition is selective because the floor 118 of the via 114 is a conductive surface which facilitates the decomposition of the precursor gases. Despite the relative selectivity of tungsten, however, small amounts of tungsten may deposit on the surfaces of the non-conductive dielectric layer 114 if the surface includes contaminants or impurities that serve as nucleation sites. Therefore, a reactive pre-clean step may be performed prior to selective WCD to remove impurities on the sidewalls 116 and floor 118 of the via 114 which may have been left after etching the dielectric layer 112 to form the via 114. A reactive pre-clean step may also be necessary to remove impurities after the deposition of the tungsten plug 120 to provide better adhesion to a subsequently deposited metal layer.

Prior to depositing the metal plug 120, the patterned or etched substrate 110 may be cleaned to remove native oxides or other contaminants from the surface thereof. Reactive gases are excited into a plasma within a remote plasma source (RPS) chamber such as a Reactive Pre-clean II chamber available from Applied Materials, Inc., located in Santa Clara, Calif. Pre-cleaning may also be done by connecting the remote plasma source to a metal CVD/PVD chamber containing the substrate 110. Alternatively, metal deposition chambers having gas delivery systems could be modified to deliver the pre-cleaning gas plasma through existing gas inlets such as a gas distribution showerhead positioned above the substrate.

In one aspect, the reactive pre-clean process forms radicals from a plasma of one or more reactive gases such as argon, helium, hydrogen, nitrogen, fluorine-containing compounds, and combinations thereof. For example, a reactive gas may include a mixture of tetrafluorocarbon (CF₄) and oxygen (O₂), or a mixture of helium (He) and nitrogen trifluoride (NF₃). More preferably, the reactive gas is a mixture of helium and nitrogen trifluoride.

The plasma is typically generated by applying a power of about 500 to 2,000 watts RF at a frequency of about 200 KHz to 114 MHz. The flow of helium ranges from about 100 to about 500 sccm and the flow of nitrogen trifluoride typically ranges from 100 sccm to 500 sccm for 200 mm substrates. The plasma treatment lasts for about 10 to about 150 seconds. Preferably, the plasma is generated in one or more treatment cycles and purged between cycles. For example, four treatment cycles lasting 35 seconds each is effective.

In another aspect, the patterned or etched substrate 110 may be pre-cleaned using first an argon plasma and then a hydrogen plasma. A processing gas comprising greater than about 50% argon by number of atoms is introduced at a pressure of about 0.8 mtorr. A plasma of the argon gas is struck to subject the substrate 110 to an argon sputter cleaning environment. The argon plasma is preferably generated by applying between about 50 watts and about 500 watts of RF power. The argon plasma is maintained for between about 10 seconds and about 300 seconds to provide sufficient cleaning time for the deposits that are not readily removed by a reactive hydrogen plasma.

Following the argon plasma, the chamber pressure is increased to about 140 mtorr, and a processing gas consisting essentially of hydrogen and helium is introduced into the processing region. Preferably, the processing gas comprises about 5% hydrogen and about 95% helium. The hydrogen plasma is generated by applying between about 50 watts and about 500 watts power. The hydrogen plasma is maintained for about 10 seconds to about 300 seconds.

Referring to FIG. 1C, a barrier layer 130 is then deposited on an upper surface of the tungsten plug 120 as well as the side walls 116 of the via 114. The barrier layer 130 acts as a diffusion barrier to prevent inter-diffusion of a copper metal to be subsequently deposited into the via 114. In one embodiment, the barrier layer 130 is a thin layer of a refractory metal having a thickness between about 50 Å and about 1000 Å. The barrier layer is preferably deposited to a thickness of about 200 Å to about 500 Å. For example, the barrier layer 130 may consist of tungsten (W), tantalum (Ta), titanium (Ti), tantalum nitride (TaN), titanium nitride (TiN), or combinations thereof, for example.

Preferably, the barrier metal is tantalum and is deposited using high density plasma physical vapor deposition (HDP-PVD) to enable good conformal coverage. One example of a HDP-PVD chamber is the Ionized Metal Plasma (IMP) Vectra™ chamber, available from Applied Materials, Inc. of Santa Clara, Calif. The IMP chamber can be integrated into an Endura™ platform, also available from Applied Materials, Inc. Of course, other techniques, such as physical vapor deposition, chemical vapor deposition, electrodeless plating, and electroplating, may be used.

The IMP chamber includes a target, coil, and biased substrate support member. Typically, a power between about 0.5 kW and about 5 kW is applied to the target, and a power between about 0.5 kW and 3 kW is applied to the coil. A power less than about 500 W at a frequency of about 13.56 MHz is applied to bias the substrate. The substrate support member is heated to a temperature between about 100° C. and 400° C. Argon is flowed into the chamber at a rate of about 35 sccm to about 85 sccm, and nitrogen may be added to the chamber at a rate of about 5 sccm to about 100 sccm. The operating pressure of the chamber is typically about 5 mTorr to about 100 mTorr to increase the ionization probability of the sputtered material atoms as the atoms travel through the plasma region.

Referring to FIGS. 1D and 1E, copper is then deposited on the barrier layer 130 to fill the via 114. In one aspect, a metal seed layer 140 of a copper-containing material is first deposited having a thickness of about 1,000 Å to about 2,000 Å using well known processing parameters for physical vapor deposition. A low temperature process may also be used to deposit the metal seed layer 140 using chemical vapor deposition techniques.

To form a copper seed layer 140 using the IMP process described above, a power between about 0.5 kW and about 5 kW is applied to the target, and a power between about 0.5 kW and 3 kW is applied to the coil. A power between about 200 and about 500 W at a frequency of about 13.56 MHz is applied to bias the substrate. Argon is flowed into the chamber at a rate of about 35 sccm to about 85 sccm, and nitrogen may be added to the chamber at a rate of about 5 sccm to about 100 sccm. The substrate support member is heated to a temperature between about 50° C. and 250° C. as the pressure of the chamber is typically between about 5 mTorr to about 100 mTorr.

Referring to FIG. 1E, a copper layer 142 is then deposited on the seed layer 140 to fill the via 114. The copper layer 142 may be deposited using CVD, PVD, or electroplating techniques. However, the copper layer 142 is preferably formed using an electroplating cell, such as the Electra™ Cu ECP system, available from Applied Materials, Inc., Santa Clara, Calif.

A copper electrolyte solution and copper electroplating technique is described in commonly assigned U.S. Pat. No. 6,113,771, entitled “Electro-deposition Chemistry”, which is incorporated by reference herein. Typically, the electroplating bath has a copper concentration greater than about 0.7M, a copper sulfate concentration of about 0.85, and a pH of about 1.75. The electroplating bath may also contain various additives as is well known in the art. The temperature of the bath is between about 15° C. and about 25° C. The bias is between about −15 volts to about 15 volts. In one aspect, the positive bias ranges from about 0.1 volts to about 10 volts and the negatives bias ranges from about −0.1 to about −10 volts.

Following copper deposition, the top portion of the structure 100 may be planarized. A chemical mechanical polishing (CMP) apparatus may be used, such as the Mirra™ System available from Applied Materials, Santa Clara, Calif., for example. During the planarization process, portions of the copper 140 and dielectric 112 are removed from the top of the structure 100 leaving a fully planar surface. Optionally, the intermediate surfaces of the structure 100 may be planarized between the deposition of the subsequent layers described above.

As stated above, the processing steps of the embodiments described herein may be performed in an integrated processing platform such as the Endura™ processing system available from Applied Materials, Inc. located in Santa Clara, Calif. To facilitate the control and automation of the overall system, the integrated processing system may include a controller 140 comprising a central processing unit (CPU) 142, memory 144, and support circuits 146. The CPU 142 may be one of any form of computer processors that are used in industrial settings for controlling various drives and pressures. The memory 144 is connected to the CPU 142, and may be one or more of a readily available memory such as random access memory (RAM), read only memory (ROM), floppy disk, hard disk, or any other form of digital storage, local or remote. Software instructions and data can be coded and stored within the memory 144 for instructing the CPU 142. The support circuits 146 are also connected to the CPU 142 for supporting the processor 142 in a conventional manner. The support circuits 146 may include cache, power supplies, clock circuits, input/output circuitry, subsystems, and the like.

### EXAMPLE 1

The following example was carried out using an integrated Endura® processing system available from Applied Materials, Inc. located in Santa Clara, Calif. having a Pre-Clean II chamber, IMP PVD Ta/TaN chamber, PVD Cu chamber, and WCVD chamber mounted thereon. A patterned or etched wafer formed according to conventional or well-known techniques was introduced into the Endura® system and degassed at 350° C. for about 40 seconds. The wafer was first transferred to the Pre-clean II chamber where about 250 Å were removed from the surface of the patterned dielectric. The wafer was next transferred to the WCVD chamber where a tungsten plug was deposited having a thickness of about 3,500 Å, which partially filled the via. A tantalum barrier layer was then deposited conformally in the via having a thickness of about 250 Å using the IMP PVD Ta/TaN chamber. The wafer was then transferred to the copper PVD chamber where a 1,000 Å thick conformal seed layer was deposited in the via. Next, the wafer was transferred into an electroplating chamber where the via was filled with copper. The wafer was then moved into a chemical mechanical polishing system to planarize the upper surface of the wafer.

While the foregoing is directed to the preferred embodiment of the present invention, other and further embodiments of the invention may be devised without departing from the basic scope thereof. The scope of the invention is determined by the claims which follow.

What is claimed is:

1. A method for forming a metal interconnect, comprising:
depositing a metal plug to at least partially fill a feature having a width less than about 0.18 microns and an aspect ratio greater than about 3:1;
depositing a barrier layer over the metal plug; and then
depositing a metal layer over the barrier layer.

2. The method of claim 1, wherein the metal plug reduces the aspect ratio to less than about 3:1.

3. The method of claim 2, wherein the metal plug reduces the aspect ratio of the feature to facilitate the deposition of the barrier layer within the feature.

4. The method of claim 2, wherein the metal plug fills less than about 50% of the feature.

5. The method of claim 1, wherein the metal plug comprises tungsten.

6. The method of claim 5, wherein the metal plug is deposited by selective chemical vapor deposition.

7. The method of claim 6, wherein the metal plug has a thickness less than about 5,000 angstroms.

8. The method of claim 1, wherein the barrier layer comprises tantalum, tantalum nitride, titanium, titanium nitride, tungsten, or tungsten nitride.

9. The method of claim 8, wherein the barrier layer is deposited by plasma enhanced chemical vapor deposition.

10. The method of claim 9, wherein the barrier layer is deposited having a thickness between about 250 angstroms and about 500 angstroms.

11. The method of claim 1, wherein the metal layer comprises copper.

12. The method of claim 11, wherein depositing the copper layer comprises first depositing a physical vapor deposition copper seed layer and then an electrochemical plating copper layer.

13. The method of claim 1, further comprising chemical mechanical polishing an upper surface of the feature.

14. The method of claim 1, further comprising reactively cleaning the feature prior to depositing the metal plug.

15. A method for forming a metal interconnect, comprising:
depositing a metal plug having a thickness less than about 5,000 angstroms to at least partially fill a feature, thereby reducing an aspect ratio of the feature to less than about 3:1;
depositing a barrier layer over the metal plug; and then
depositing a metal layer over the barrier layer.

16. The method of claim 15, wherein the feature has a width less than about 0.18 microns.

17. The method of claim 15, wherein the metal plug is deposited by selective chemical vapor deposition.

18. The method of claim 15, wherein the barrier layer comprises tantalum, tantalum nitride, titanium, titanium nitride, tungsten, or tungsten nitride.

19. The method of claim 18, wherein the barrier layer is deposited by plasma enhanced chemical vapor deposition.

20. The method of claim 19, wherein the barrier layer is deposited having a thickness between about 250 angstroms and about 500 angstroms.

21. The method of claim 15, wherein the metal layer comprises copper.

22. The method of claim 21, wherein depositing the metal layer comprises first depositing a physical vapor deposition copper seed layer and then an electrochemical plating copper layer.

23. A method for forming a metal interconnect, comprising:
depositing a first layer comprising a metal having a lower propensity to electromigrate to at least partially fill a feature; and then
depositing a second layer comprising a metal having a higher propensity to electromigrate to fill the feature.

24. The method of claim 23, wherein the metal having a lower propensity to electromigrate comprises tungsten deposited by selective chemical vapor deposition.

25. The method of claim 23, further comprising depositing a barrier layer over the first layer prior to depositing the second layer.

26. The method of claim 25, wherein the barrier layer comprises tantalum, tantalum nitride, titanium, titanium nitride, tungsten, or tungsten nitride.

27. The method of claim 23, wherein the metal having a higher propensity to electromigrate comprises copper.

28. The method of claim 23, wherein depositing the second layer comprising a metal having a higher propensity to electromigrate comprises first depositing a physical vapor deposition copper seed layer and then an electrochemical plating copper layer.

29. An integrated processing system for at least partially forming a metal interconnect, comprising:
means for depositing a metal plug to at least partially fill a feature having a width less than about 0.18 microns to reduce an aspect ratio of the feature to less than about 3:1;
means for depositing a barrier layer over the tungsten plug; and
means for depositing a copper layer over the barrier layer.

30. The system of claim 29, wherein the metal plug comprises tungsten.

31. The system of claim 29, wherein the barrier layer comprises tantalum, tantalum nitride, titanium, titanium nitride, tungsten, or tungsten nitride.

32. The system of claim 29, wherein depositing the copper layer comprises first depositing a physical vapor deposition copper seed layer and then an electrochemical plating copper layer.

33. The system of claim 29, further comprising means for chemical mechanical polishing an upper surface of the feature.

34. The system of claim 29, further comprising means for reactively cleaning the feature prior to depositing the metal plug.
